(19) United States
(12) Patent Application Publication
(10) Pub. No.: US 2024/0080977 A1
(43) Pub. Date: Mar. 7, 2024

(54) INDUCTOR WITH INTEGRATED CONDUCTORS FOR POWER MODULES

(71) Applicant: Renesas Electronics America Inc., Milpitas, CA (US)

(72) Inventors: Zhizheng LIU, Fremont, CA (US); Haiyu ZHANG, Sunnyvale, CA (US); Sri Ganesh A THARUMALINGAM, Fremont, CA (US); Mark Alan KWOKA, Palm Bay, FL (US); Yonggoo EOM, Danville, CA (US)

(73) Assignee: Renesas Electronics America Inc., Milpitas, CA (US)

(21) Appl. No.: 18/313,518

(22) Filed: May 8, 2023

Related U.S. Application Data
(60) Provisional application No. 63/403,941, filed on Sep. 6, 2022.

(51) Int. Cl. H05K 1/11; H01F 27/30; H05K 1/16

(52) U.S. Cl. CPC H05K 1/111; H01F 27/306; H05K 1/165

(57) ABSTRACT

According to an example, a structure is generally described. The structure may include an inductor core having a plurality of surfaces; and at least one conductor integrated with at least one surface of the plurality of surfaces of the inductor core.

### CROSS-REFERENCE TO RELATED APPLICATION

This application is based upon and claims the benefit of priority under 35 USC 119(e) of U.S. Provisional Patent Application No. 63/403,941 filed on Sep. 6, 2022, and titled Inductor with Integrated Conductors for Power Modules, the entire disclosure of which is incorporated herein by reference in its entirety.

### BACKGROUND

Unless otherwise indicated herein, the materials described in this section are not prior art to the claims in this application and are not admitted to be prior art by inclusion in this section. The present disclosure relates in general to systems and methods of integrating semiconductor devices, and more particularly, to the integrated assembly of a power converter.

High power density power modules have a wide range of applications. These modules may be designed to deliver high levels of power output in a compact form factor, with high efficiency and high reliability. To meet the increasing current requirements and more stringent dynamic load transient requirements of increasingly dense application specific integrated circuits (ASICs), graphics processing units (GPUs), and the like, board-mounted power modules with power devices located on a top surface of the power module to enable topside cooling can improve thermal performance at the cost of additional electrical connections between the top surface and the bottom. In general, at least one inductive component, such as inductor, may be integrated into the power module. However, the existing power module designs may include a printed circuit board (PCB) or connector box to build up the electrical connections and provide mechanical support. Such adjacent or surrounding structures may be inefficient and may limit the inductor size. What is needed is a solution that addresses these issues, and others.

### SUMMARY

According to an example, a structure is generally described. The structure may include an inductor core having a plurality of surfaces; and at least one conductor integrated with at least one surface of the plurality of surfaces of the inductor core.

According to this example, the structure wherein the inductor core has six sides arranged in three pairs of opposing sides and surrounding an inductor core volume, each side of the inductor core has an external surface. The structure wherein the at least one conductor passes through at least a portion of the inductor core volume. The structure wherein the at least one conductor integrated with at least one surface of the inductor core is included in a plurality of conductors, each of the plurality of conductors being integrated with at least one surface of the plurality of surfaces of the inductor core, and wherein a subset of the plurality of conductors is at least one of an electrical conductor and a thermal conductor.

According to this example, the apparatus may further include an inductor winding disposed at least partially within the inductor core volume, the inductor winding and the inductor core forming an inductor, the inductor winding having a first lead attached to a first conductor of the plurality of conductors, the first conductor being integrated with at least one of the surfaces of the plurality of surfaces of the inductor core, the inductor winding having a second lead attached to a second conductor of the plurality of conductors, the second conductor being integrated with at least one of the plurality of surfaces of the inductor core. The structure wherein the first conductor and the second conductor are integrated with one of a same surface of the plurality of surfaces of the inductor core and a different surface of the plurality of surfaces of the inductor core. The structure may further include a power stage disposed on a first surface of the inductor core and coupled to the inductor winding, the power stage being electrically coupled to a power source and a controller through a plurality of conductors integrated with a second surface of the inductor core to form a single-phase power controller. The structure wherein the at least one conductor spans a plurality of inductor core surfaces.

According to this example, the apparatus wherein the plurality of inductor core surfaces are at least one of: disposed adjacent to each other, the at least one conductor being configured to span between two surfaces and four surfaces of the plurality of inductor core surfaces; and disposed opposite from each other, the at least one conductor being configured to span between three surfaces and four surfaces of the plurality of inductor core surfaces. The structure wherein the plurality of inductor core surfaces are disposed opposite from each other are parallel to each other. The structure wherein the inductor core includes an opening disposed within the inductor core that spans between a bottom surface and top surface of the inductor core. The structure wherein the opening has a cross-sectional profile of a cross, a square, a diamond, a hexagon, an octagon, and a circle.

According to an example, an apparatus generally described. The apparatus may include an inductor core having six sides arranged in three pairs of substantially parallel surfaces and forming an inductor core volume; a plurality of conductors, each of the plurality of conductors being integrated with at least one surface of the inductor core; and an inductor winding disposed at least partially within the inductor core volume, the inductor winding and the inductor core forming an inductor, the inductor winding having a first lead attached to a first conductor of the plurality of conductors, the first conductor being integrated with at least one of the surfaces of the inductor core, the inductor winding having a second lead attached to a second conductor of the plurality of conductors, the second conductor being integrated with at least one of the surfaces of the inductor core.

According to this example, the apparatus wherein the first conductor and the second conductor are integrated with one of a same surface of the plurality of surfaces of the inductor core and a different surface of the plurality of surfaces of the inductor core. The apparatus wherein the inductor winding is a first inductor winding, the apparatus further comprising: a second inductor winding disposed at least partially within the inductor core volume and disposed adjacent to the first inductor winding, the second inductor winding and the inductor core forming a second inductor, the second inductor winding having a third lead attached to a third conductor of the plurality of conductors, the third conductor being integrated with at least one of the surfaces of the inductor core, the second inductor winding having a fourth lead attached to a fourth conductor of the plurality of conductors, the fourth conductor being integrated with at least one of the surfaces of the inductor core.

According to this example, the apparatus may further include an opening disposed within the inductor core between the first inductor winding and the second inductor winding, the opening spans between a bottom surface of the inductor core and top surface of the inductor core, wherein the opening has a cross-sectional profile of a cross, a square, a diamond, a hexagon, an octagon, and a circle. The apparatus may further include a first power stage disposed on a top surface of the inductor core and coupled to the first inductor winding, the first power stage being coupled to a power source and a first controller through a first plurality of conductors integrated with at least one of a plurality of side surfaces of the inductor core; and a second power stage disposed on the top surface of the inductor core and disposed adjacent to the first power stage, the second power stage being coupled to the second inductor winding, the second power stage being coupled to the power source and a second controller through a second plurality of conductors integrated with at least one of the plurality of side surfaces of the inductor core, wherein the first power stage coupled with the first inductor winding and the second power stage coupled with the second inductor winding form a dual-phase power module.

According to this example, the apparatus may further include a third inductor winding disposed at least partially within the inductor core volume and disposed adjacent to the first inductor winding and the second inductor winding, the third inductor winding and the inductor core forming a third inductor; a third power stage disposed on the top surface of the inductor core and disposed adjacent to the second power stage, the third power stage being coupled to the third inductor winding, the third power stage being coupled to the power source and a third controller through a third plurality of conductors integrated with at least one of the plurality of side surfaces of the inductor core; a fourth inductor winding disposed at least partially within the inductor core volume and disposed diagonally opposite the first inductor winding, the fourth inductor winding and the inductor core forming a fourth inductor; and a fourth power stage disposed on the top surface of the inductor core and disposed adjacent to both the third power stage and the first power stage, the fourth power stage being coupled to the fourth inductor winding, the fourth power stage being coupled to the power source and a fourth controller through a fourth plurality of conductors integrated with at least one of the plurality of side surfaces of the inductor core, wherein the first power stage coupled with the first inductor winding, the second power stage coupled with the second inductor winding, the third power stage coupled with the third inductor winding, and the fourth power stage coupled with the fourth inductor winding form a quad-phase power module. The apparatus may further include an opening disposed centrally within the inductor core between the first inductor winding, the second inductor winding, the third inductor winding, and the fourth inductor winding, the opening spans between a bottom surface of the inductor core and top surface of the inductor core, wherein the opening has a cross-sectional profile of a cross, a square, a diamond, a hexagon, an octagon, and a circle.

According to an example, a method of forming a structure is generally described. The method may include forming an inductor core having a plurality of surfaces; and integrating at least one conductor with at least one surface of the plurality of surfaces of the inductor core.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1A is a diagram showing an example structure that can implement inductor with integrated conductors for power modules in one embodiment.

FIG. 1B is a diagram showing another example structure that can implement inductor with integrated conductors for power modules in one embodiment.

FIG. 1C shows another example structure that can implement inductor with integrated conductors for power modules in one embodiment.

FIG. 2A shows additional details of an inductor with integrated conductors for power modules in one embodiment.

FIG. 2B shows additional details of an inductor with integrated conductors for power modules in one embodiment.

FIG. 3A shows an example configuration of an inductor with integrated conductors for power modules in one embodiment.

FIG. 3B shows one or more perspectives of the example configuration of FIG. 3A in one embodiment.

FIG. 4A shows another example configuration of an inductor with integrated conductors for power modules in one embodiment.

FIG. 4B shows one or more perspectives of the example configuration of FIG. 4A in one embodiment.

FIG. 5A shows another example configuration of an inductor with integrated conductors for power modules in one embodiment.

FIG. 5B shows one or more perspectives of the example configuration of FIG. 5A in one embodiment.

FIG. 6A shows another example configuration of an inductor with integrated conductors for power modules in one embodiment.

FIG. 6B shows one or more perspectives of the example configuration of FIG. 6A in one embodiment.

FIG. 7 shows a perspective view of another example power module that can implement an inductor with integrated conductors for power modules in one embodiment.

FIG. 8 is a diagram showing a perspective view of another example power module that can implement an inductor with integrated conductors for power modules in one embodiment.

FIG. 9 is a diagram showing a perspective view of another example power module that can implement an inductor with integrated conductors for power modules in one embodiment.

### DETAILED DESCRIPTION

The present disclosure will now be described in greater detail by referring to the following discussion and drawings that accompany the present application. It is noted that the drawings of the present disclosure are provided for illustrative purposes only and, as such, the drawings are not drawn to scale. It is also noted that like and corresponding elements that are present in the drawings are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present disclosure may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

A structure described includes an inductor to provide mechanical support and conductors that are integrated in the inductor core, such that there may be no need for a connector box or adjacent side structures as described above. The structure described herein can reduce device size of power modules, and provide flexibility in the size of the inductor (e.g., inductor size is maximized for given package dimensions), and potentially reduce the production cost of power modules since connector box and side structures may no longer be needed between top and bottom boards to provide the mechanical support. Integrating (e.g., attaching) the conductors with the inductor core can improve thermal performance of the power module as well by conducting heat away from the power module, even if the thermal conductor is not used as an electrical conductor. Further, conductors integrated with one or more inductors in one or more embodiments can provide robust electrical connections and achieve optimal heat dissipation while maximizing inductor size for a given form factor.

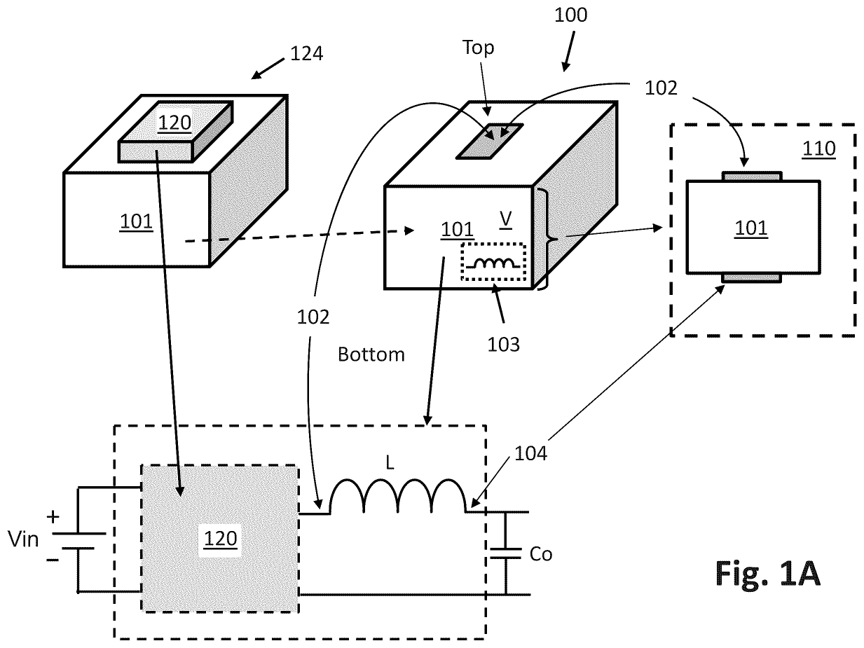

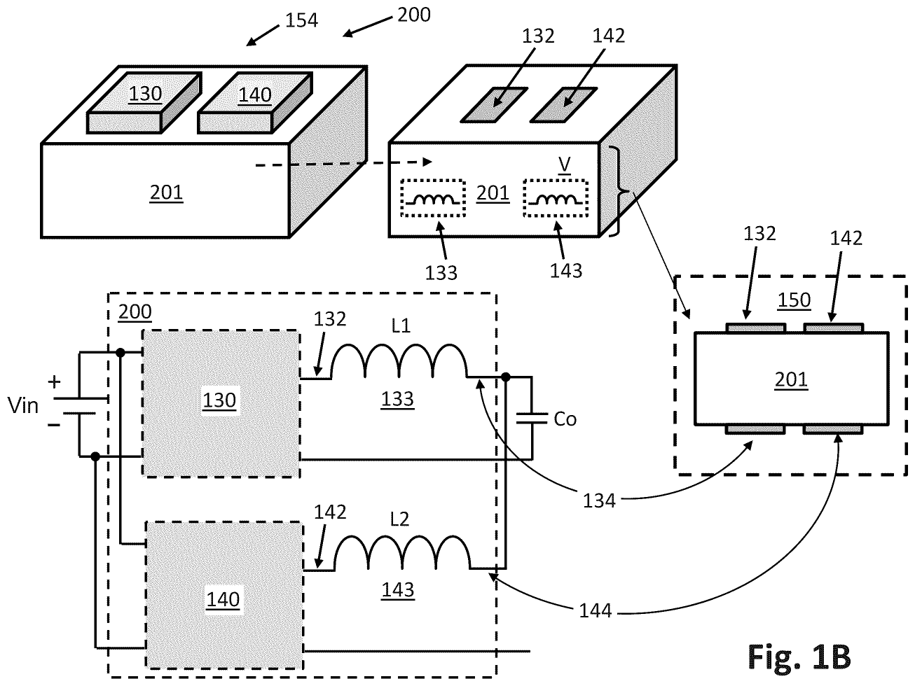

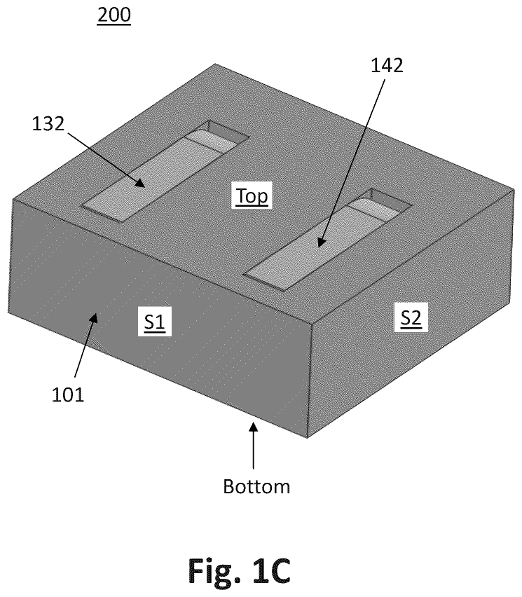

FIG. 1A is a diagram showing an example structure that can implement an inductor with integrated conductors for power modules in one embodiment. In an example shown in FIG. 1A, a structure 100 can be a semiconductor package or semiconductor device. Structure 100 can include an inductor core 101 and one or more inductor windings or coils 103. In one embodiment, inductor core 101 can be composed of nonconductive materials (e.g., plastic) or magnetic materials (e.g., silicon steel, ferrites). In an aspect, inductor core 101 can be configured to store energy. Inductor core 101 can function as a medium to concentrate and contain magnetic flux induced by windings 103. Inductor core 101 and windings 103 can form an inductor labeled as L in FIG. 1A.

Windings 103 can be fully or at least partially enclosed in inductor core 101. One or more portions, such as terminals (e.g., ends) of windings 103 can be exposed on one or more external surfaces of inductor core 101 having six sides arranged with three pairs of opposing sides arranged generally in a cuboid shape (e.g., a regular hexahedron). The corners or vertices or edges of the generally cuboid shape may be cut or shaved in some examples to form a truncated hexahedron without departing from the scope of this disclosure. The opposing sides may be substantially parallel to each other. Each side of the inductor core has a corresponding external surface which faces outward, away from an interior region of inductor core 101. In one example, inductor core 101 has a plurality of sides that enclose an inductor core volume V sufficient to at least partially or fully enclose the one or more windings 103.

In an example, inductor core 101 has six sides with three pairs of opposing surfaces and surrounding or forming inductor core volume V. Each side of the plurality of sides of inductor core 101 may include a planar region or planar portion, or the entire side may be substantially planar in shape to facilitate mounting of conductors, conducting pads, and the like. Further, the planar regions of opposing sides may be substantially parallel to each other. In this manner, a top side may have a planar region that is substantially parallel to an opposing bottom side planar region, a left side may have a planar region that is substantially parallel to an opposing right side planar region, and a front end side may have a planar region that is substantially parallel to an opposing back side planar region. The terms top, bottom, left, right, front, and back are relative terms and the identified labels are used for convenience based on a particular view illustrated in the drawings, for example. Different labels, and different label assignments may be used for different views or the same view.

In an end perspective view 110 shown in FIG. 1A, terminals 102, 104 of windings 103 are exposed on a top surface and a bottom surface, respectively, of inductor core 101. In this manner, winding 103 may include a first lead attached to a first conductor as a contact or terminal 102, and winding 103 may include a second lead attached to a second conductor as terminal 104 to provide continuity between terminal 102, winding 103, and terminal 104. The exposure of terminals 102, 104 can facilitate electrical connection of inductor L to other devices. Inductor core 101 may be manufactured with some or all of the needed conductors and contacts prior to assembly into a power module, for example.

In the example shown in FIG. 1A, an electronic device 120 can be positioned on a top surface of structure 100 for better thermal performance (e.g., unimpeded heat radiation) and so that device 120 can be coupled to structure 100 via terminal 102. In one or more embodiments, device 120 can be a power stage (or other electronic component) such that the coupling of device 120 to structure 100 forms a single-phase power module 124. As used herein, power stage 120 coupled with an inductor and a module controller may form power module 124. In one embodiment, device 120 can be placed directly on top of inductor core 101 without any intervening layers or structures. To be described in more detail below, structure 100 can include additional conductors (e.g., conductive materials such as copper) or contacts (e.g., in addition to terminals 102, 104) that can be integrated in inductor core 101 and exposed on surfaces of inductor core 101 to facilitate transmission of input and output (I/O) signals between devices (e.g., device 120) and structure 100 with other electronic components including a power supply, a processor, a power stage controller, and the like. Alternatively, some or all functions of a power stage controller may be incorporated into device 120. For example, input voltage Vin (Vin+) and ground (Vin−) can be provided to device 120 via conductors integrated with inductor core 101. As used herein, conductors that are integrated with inductor core 101 may include a copper trace, a wire (e.g., formed of copper, aluminum, or another conductive material), a pad, a contact, a conductive region, or the like, attached to a portion of a surface of inductor core 101, or at least partially embedded in a surface of inductor core 101 so that other components may be able to make electrical and/or thermal contact with the conductor, as will be more fully described below.

FIG. 1B is a diagram showing another example structure that can implement an inductor with integrated conductors for power modules in one embodiment. Structure 100 shown in FIG. 1A can include additional conductors, and the additional conductors can allow structure 100 to be coupled to additional devices. Structure 100 can also include more than one set of inductor windings. In an example shown in FIG. 1B, structure 200 can include inductor core 201 similar to inductor core 101 described herein, a first inductor winding 133 (e.g., set of coils), and a second inductor winding 143 (e.g., set of coils) may be disposed at least partially within inductor core volume V. Inductor core 201 can function as a medium to concentrate and contain magnetic flux induced by windings 133, 143. Inductor core 201 and inductor winding 133 can form an inductor L1 in FIG. 1B, and inductor core 201 and inductor winding 143 can form an inductor L2 in FIG. 1B, for example. The location of first inductor winding 133 and second inductor winding 134 within inductor core 201 may vary. For example, first inductor winding 133 may be disposed adjacent to second inductor winding 134 either vertically or horizontally (as illustrated) within inductor core volume V (e.g., an interior region of inductor core 201). In this way, structure 200 and inductor core 201 are similar in some ways to structure 100 and inductor core 101 illustrated in FIG. 1A.

Inductor windings 133, 143 can be enclosed (fully or partially) in inductor core 201. One or more portions, such as terminals, or contacts of windings 133, 143 can be exposed on one or more surfaces of inductor core 201. In a side perspective view 150 shown in FIG. 1B, terminals 132, 142 of windings 133, 143 are exposed on the top surface of inductor core 201, respectively. Terminals 134, 144 of windings 133, 143 are exposed on the bottom surface of inductor core 201, respectively. The exposure of terminals 132, 134, 142, 144 can facilitate electrical connection of inductors L1, L2 to other devices. Terminals 132, 134, 142, 144 can be conductors (e.g., formed of and by conductive materials).

In the example shown in FIG. 1B, electronic devices 130, 140 can be positioned on top of structure 200 for better thermal performance and so that devices 130, 140 can be coupled to structure 200 via terminals 132, 142, respectively. In one or more embodiments, devices 130, 140 can be power stage circuits such that the coupling of devices 130, 140 to structure 200 with two power stages and two inductor windings may form a dual-phase power module 154. In one embodiment, devices 130, 140 can be placed directly on a top surface of inductor core 201, as illustrated, without any intervening layers or structures. For example, I/O pads can be created on the top and bottom surfaces of inductor core 201, and devices 130, 140, or other devices can be soldered to the I/O pads.

In one example, a solder paste may be applied to various contacts, even those contacts between components, and the solder paste may be heated sufficiently to cause the solder to flow and form a durable connection between the contacts. Other soldering methods may be used. To be described in more detail below, structure 200 can include additional conductors, such as metal pillars, metal sheets and/or metal plating using various methods. In one embodiment, the conductors can be composed of conductive materials, such as copper, copper sheet, a copper alloy, or copper plating. Conductors may be attached to a particular side and/or surface of inductor core 201 using an adhesive such as a heat-tolerant (e.g., high temperature) glue or epoxy. After attaching (e.g., integrating) the conductor with a side/surface of inductor core 201, an insulating material may be added to some portions of the attached conductor to prevent shorting and to preserve or better secure the attached conductor. These conductors can be integrated on surfaces of inductor core 101 and/or inside a body of inductor core 201 to facilitate transmission of I/O signals between devices (e.g., device 120) and structure 200. For example, input voltage Vin can be provided to devices 130, 140 via conductors integrated with inductor core 201.

FIG. 1C shows another example structure that can implement inductor with integrated conductors for power modules in one embodiment. Another example of structure 200 is shown in FIG. 1C. In the example shown in FIG. 1C, inductor core 201 can include a top surface, a bottom surface, and a plurality of faces or sides such as S1, S2, etc. Terminals 132, 142 are shown on a top surface of inductor core 201. To be described below, conductors can be added to overlay portions of one or more of a top surface, a bottom surface, and a side surface (S1, S2, and the like) of inductor core 201.

In some embodiments, portions of the conductors can be inserted through a portion of inductor core 201 where at least one portion of a conductor may pass through at least a portion of the inductor core volume. Such a connection passing through at least a portion of inductor core 201 may connect two or more sides of inductor core 201 and could be used as a jumper connection or to provide a more accessible connection point. In one or more embodiments, structures such as a connector box including contact pads and/or conductors can be integrated and enclosed within an interior region of inductor core 201. In one example, a conductor (e.g., a wire) may pass from a point inside inductor core 201 through a portion of a side of inductor core 201 to a contact or pad on an external surface of the inductor core. In this manner, a connection can be made between an inductor winding 133/143 and a connected component.

As mentioned briefly above, some contacts or conductors may provide improved thermal performance by conducting heat away from higher temperature components toward a lower temperature portion of the board, while other contacts or conductors may have a larger size (e.g., greater than is needed to handle expected current) in order to provide a larger heat radiation capability in various locations where heat dissipation may be limited, or in locations where heat may be expected to build up. Some conductors may be used solely as thermal conductors which do not conduct electrical signals or power. Other conductors may have various size characteristics to function both as electrical conductors and thermal conductors. In this manner, a subset of the plurality of conductors may be at least one of an electrical conductor and a thermal conductor.

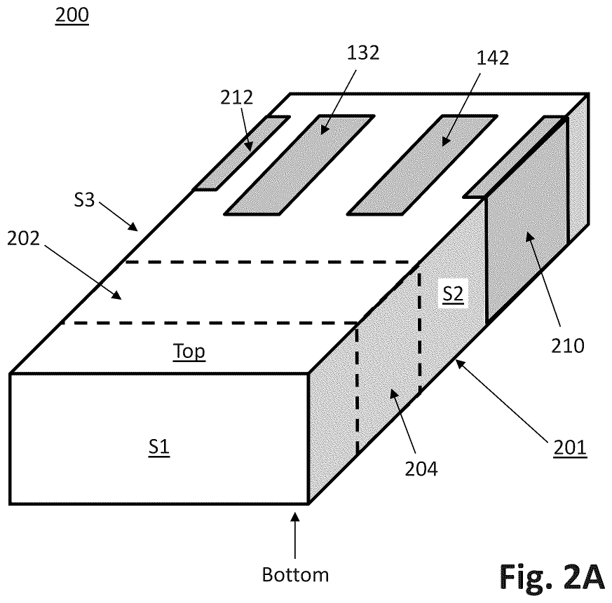

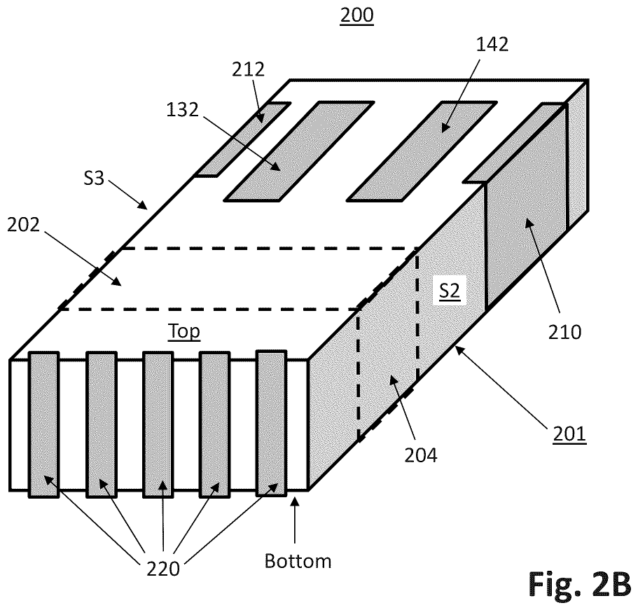

FIG. 2A shows additional details of an inductor with integrated conductors for power modules in one embodiment. In the example shown in FIG. 2A, conductive materials can overlay the side S2 and portions of the top and bottom surfaces of inductor core 201 forming a conductor 210. Conductive materials can overlay another side S3 and portions of the top and bottom surfaces of inductor core 201 forming a conductor 212, where side S3 is an opposite face or side from side S2. Conductors 210, 212 may span from the top surface of inductor core 201 to the bottom surface of inductor core 201 and may span three adjacent sides of inductor core 201, for example. Conductors 210, 212 can be positioned on inductor core 201 for connecting to specific parts of another device or circuit. For example, in response to coupling devices 130, 140 in FIG. 1B to structure 200, conductors 210, 212 can connect devices 130, 140 to ground (Vin−), respectively. A portion 202 of the top surface of inductor core 201, a portion 204 of side S2, and other portions of bottom surface and other sides of inductor core 201, can include conductive materials arranged in different shapes and/or sizes depending on the devices that can be coupled to structure 200.

In an example shown in FIG. 2B, additional conductive materials may form a plurality of vertically oriented conductors 220. Thus, conductors 220 can span from the top surface of inductor core 201 to the bottom surface of inductor core 201. Such conductors may be used to connect adjacent components in the final assembly, and may not connect with one or more inductor windings, for example. In some examples, a connecting band may surround a portion of inductor core 201 (e.g., in the region marked by 202/204) such that an electrically and/or thermally continuous band may encompass four sides of inductor core 201. Such a large connecting band may be useful to accommodate higher currents, higher temperatures, and/or to facilitate connection point flexibility during assembly. According to various examples disclosed herein, a single conductor may span one, two, three, or four sides of inductor core 201. Such a single conductor may be composed of connector segments that are electrically and/or thermally connected.

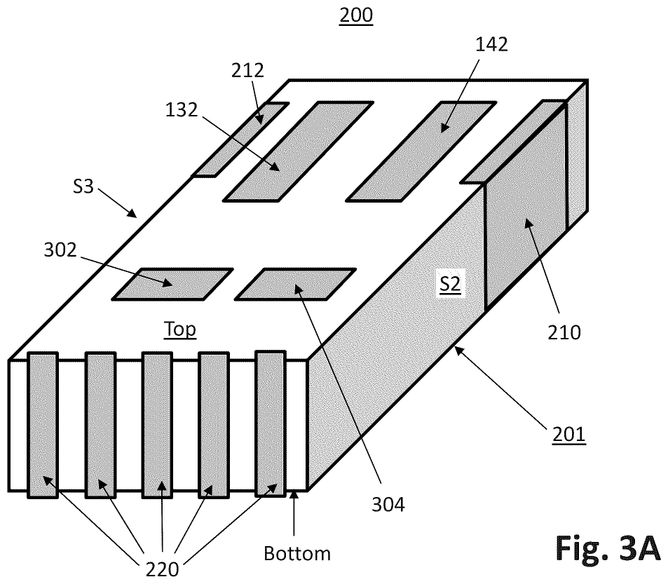

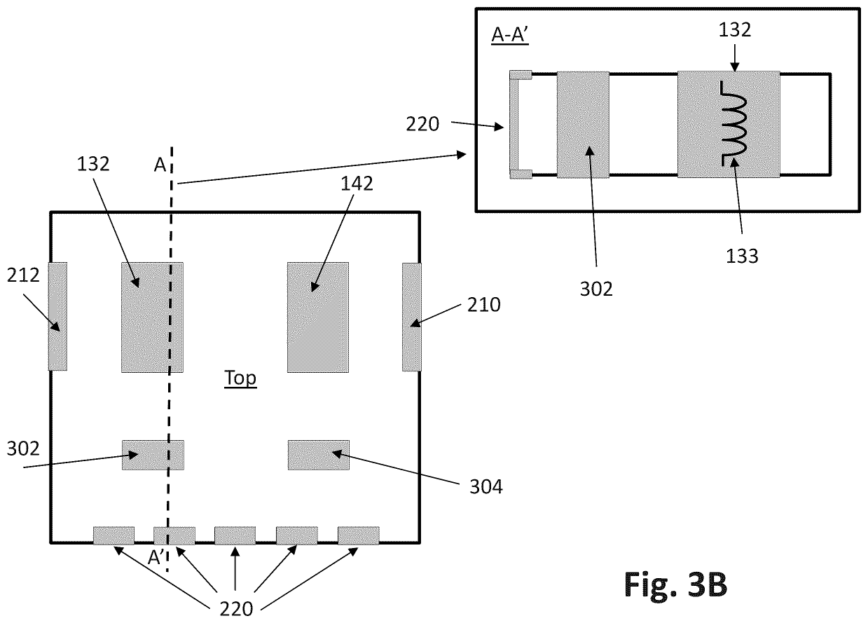

FIG. 3A shows an example configuration of an inductor with integrated conductors for power stages (e.g., power modules) in one embodiment. In the example shown in FIG. 3A, in addition to conductors 210, 212 and 220, conductive materials can be integrated in inductor core 201 to form conductors 302, 304. In one embodiment, conductors 302, 304 can be inserted through inductor core 201 and portions of conductors 302, 304 can be exposed on the bottom surface of inductor core 201. Referring to the example shown in FIG. 1A and FIG. 1B, one or more input filters (e.g., LC filters) can be disposed between the input voltage Vin and the devices 120, 130, 140. In response to devices 130, 140 being coupled to structure 200 as shown in FIG. 1B, conductors 302, 304 can facilitate transfer of input voltage Vin from a voltage source to devices 130, 140, respectively.

FIG. 3B shows one or more perspectives of the example configuration of FIG. 3A in one embodiment. FIG. 3B shows a top perspective view including an arrangement or configuration of conductors 210, 212, 220, 302, 304 on the top surface of inductor core 201. A cross sectional area A-A′ is also shown in FIG. 3B, where conductor 302 is shown as being inserted through inductor core 201 and windings 133 are shown to be enclosed by inductor core 201.

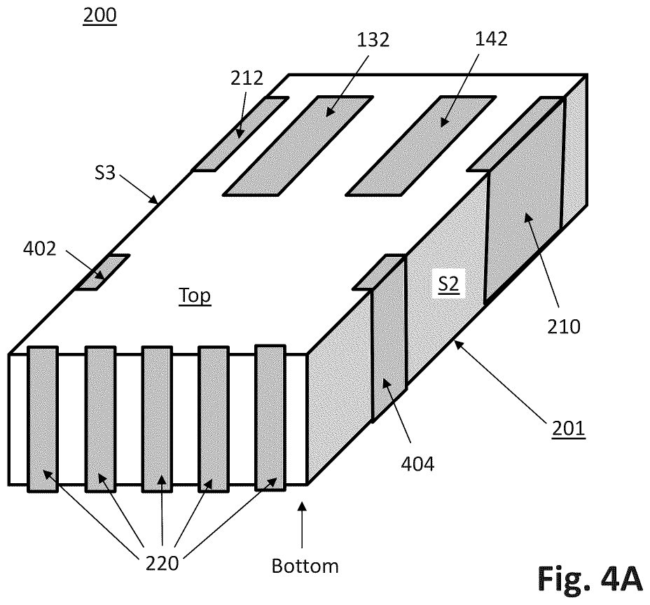

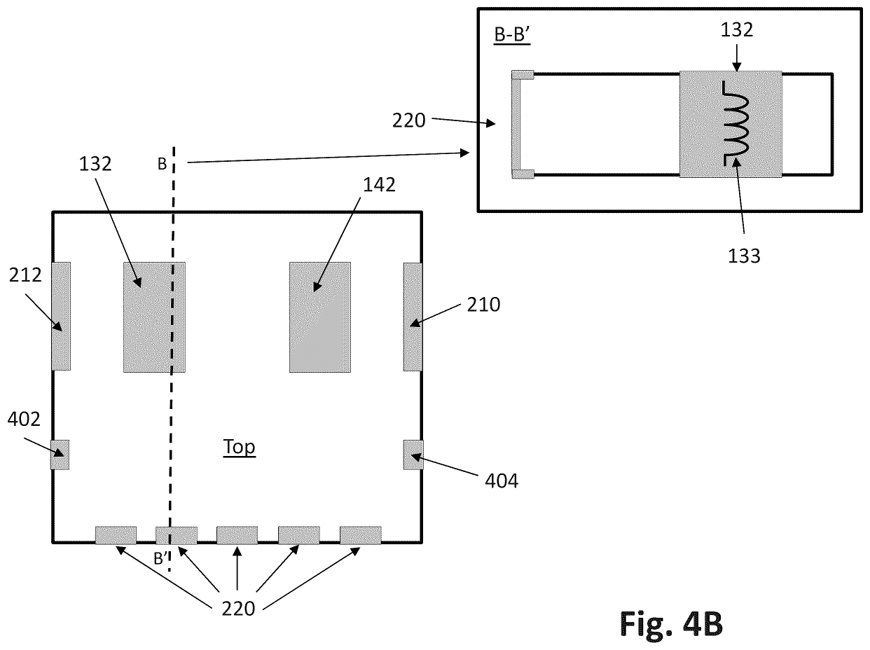

FIG. 4A shows another example configuration of an inductor with integrated conductors for power modules in one embodiment. In the example shown in FIG. 4A, in addition to conductors 210, 212 and 220, conductive materials can overlay the sides S2 and S3 and portions of the top and bottom surfaces of inductor core 201 to form conductors 402, 404. Conductor 402 can overlay side S3 and portions of the top and bottom surfaces of inductor core 201. Conductor 404 can overlay side S2 and portions of the top and bottom surfaces of inductor core 201. Conductors 402, 404 can span from the top surface of inductor core 201 to the bottom surface of inductor core 201 on sides S3, S2, respectively.

FIG. 4B shows one or more perspectives of the example configuration of FIG. 4A in one embodiment. The example in FIG. 4B shows a top perspective view including an arrangement or configuration of conductors 210, 212, 220, 402, 404 on the top surface of inductor core 201. A cross sectional area B-B′ is also shown in FIG. 4B, where conductors 402, 404 are not being inserted through inductor core 201. Referring to the example shown in FIG. 1B, in response to devices 130, 140 being coupled to structure 200 as shown in FIG. 1B, conductors 402, 404 can facilitate transfer of input voltage Vin (Vin+) from a voltage source (e.g., a power supply) to devices 130, 140, respectively.

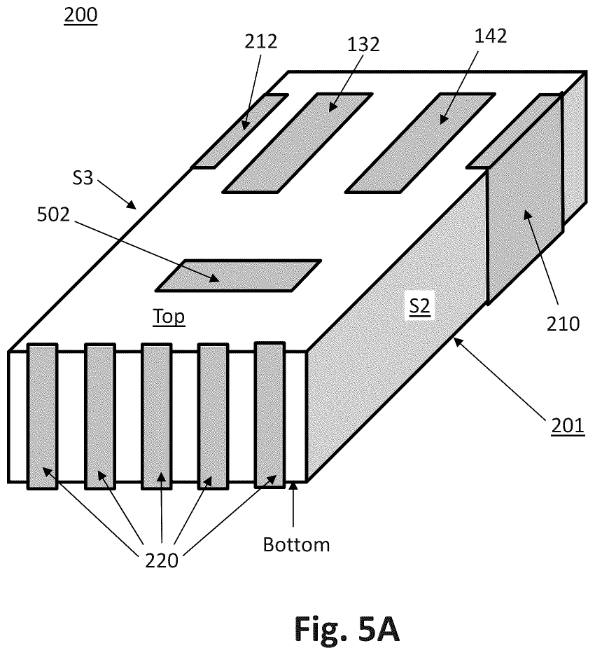

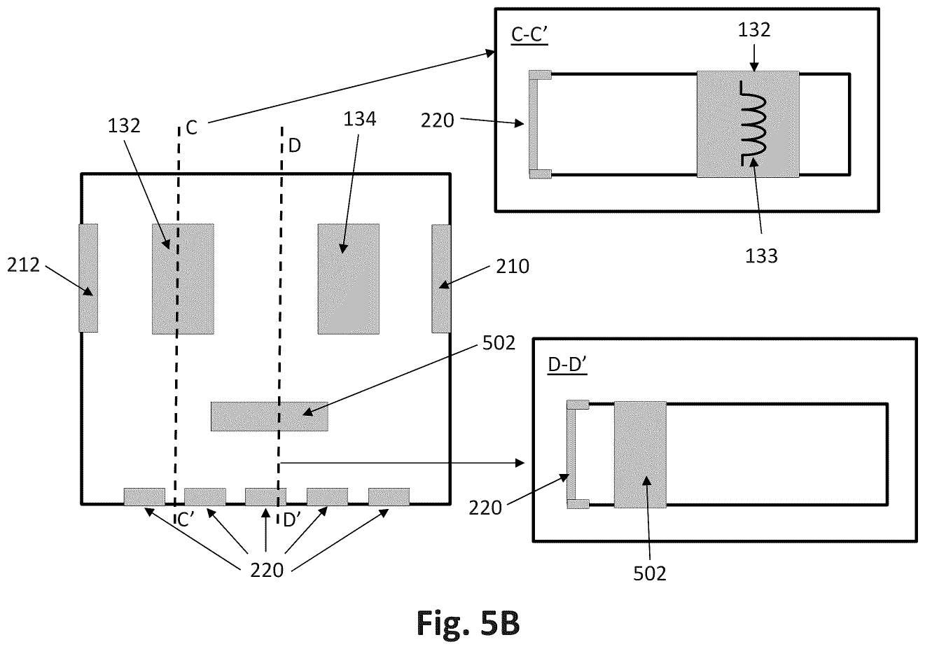

FIG. 5A shows another example configuration of an inductor with integrated conductors for power modules in one embodiment. In the example shown in FIG. 5A, in addition to conductors 210, 212 and 220, conductive materials can be integrated in inductor core 201 to form a conductor 502. In one embodiment, conductor 502 can be inserted through inductor core 201 and portions of conductor 502 can be exposed on the bottom surface of inductor core 201. Referring to the example shown in FIG. 1B, in response to devices 130, 140 being coupled to structure 200 as shown in FIG. 1B, conductor 502 can facilitate transfer of input voltage Vin from a voltage source to devices 130, 140, respectively.

FIG. 5B shows one or more perspectives of the example configuration of FIG. 5A in one embodiment. FIG. 5B shows a top perspective view including an arrangement or configuration of conductors 210, 212, 220, 502 on the top surface of inductor core 201. A cross sectional area C-C′ is also shown in FIG. 5B, where windings 133 are shown to be enclosed by inductor core 201. A cross sectional area D-D′ is also shown in FIG. 5B, where conductor 502 is shown as being inserted through inductor core 201.

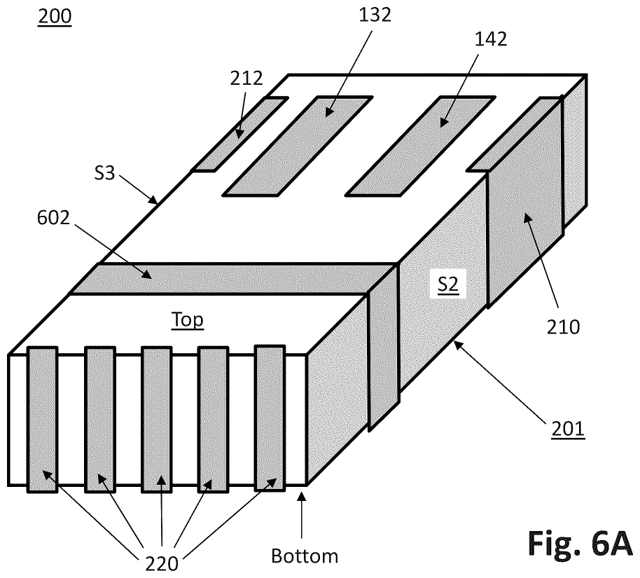

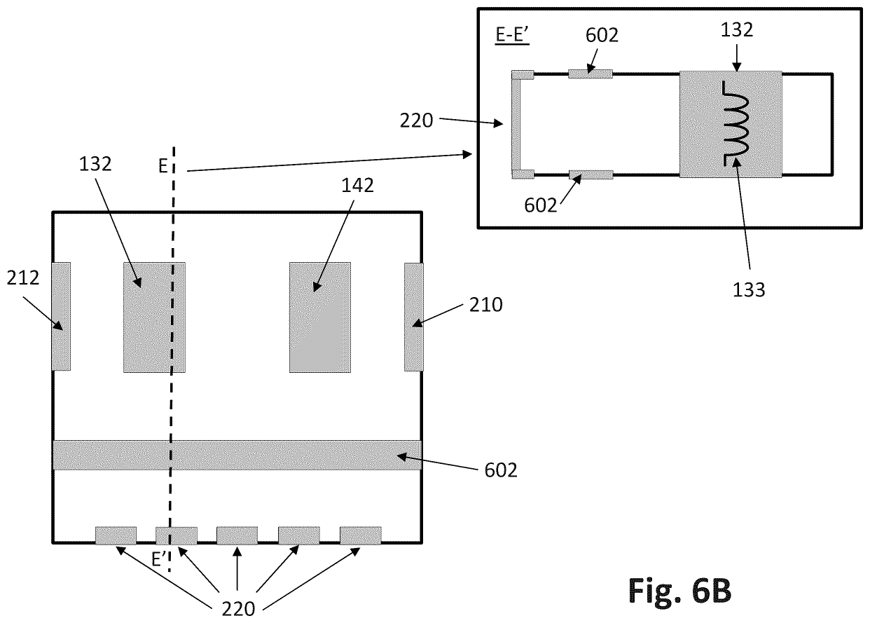

FIG. 6A shows another example configuration of an inductor with integrated conductors for power modules in one embodiment. In the example shown in FIG. 6A, in addition to conductors 210, 212 and 220, conductive materials can overlay the sides S2, S3 and the top and bottom surfaces of inductor core 201 to form a conductor 602. Conductor 602 can encompass a perimeter spanning sides S2, S3, and the top and bottom surfaces of inductor core 201 (e.g., a wrap around conductor as with the 4-sided connecting band described above).

FIG. 6B shows one or more perspectives of the example configuration of FIG. 6A in one embodiment. The example in FIG. 6B shows a top perspective view including an arrangement or configuration of conductors 210, 212, 220, 602 on the top surface of inductor core 201. A cross sectional area E-E′ is also shown in FIG. 6B, where conductor 602 is not being inserted through inductor core 201, but may be attached to the top and bottom surfaces of inductor core 201. Referring to the example shown in FIG. 1B, in response to devices 130, 140 being coupled to structure 200 as shown in FIG. 1B, conductor 602 can facilitate transfer of input voltage Vin from a voltage source to devices 130, 140, respectively.

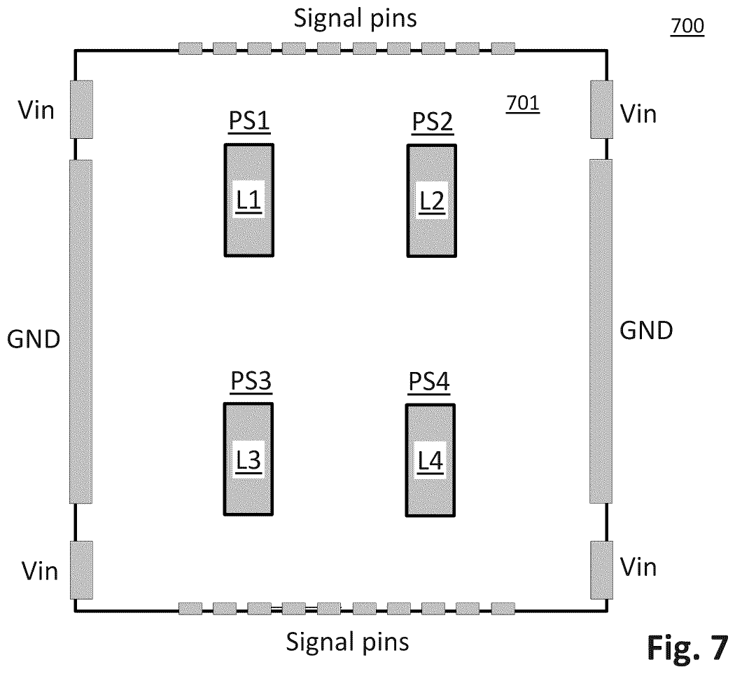

FIG. 7 shows a perspective view of another example of an inductor core with integrated conductors for use with a plurality of power stages (e.g., power modules) in one embodiment. FIG. 7 shows a top perspective view of a quad-phase (e.g., four phases) or multi-phase power module 700 including an arrangement or configuration of inductors and conductors on the top surface of inductor core 701 similar to inductor core 101 described herein. In this case, a corresponding power stage (PS1, PS2, PS3, PS4) may be connected to each of the inductors (L1, L2, L3, L4) in a one-to-one fashion. The relative position and orientation of PS1:L1, and the like, is approximate and is intended to convey that inductor L1 and associated power module PS1 are located adjacent to both inductor L2 and associated power module PS2 and inductor L3 and associated power module PS3. Similarly, inductor L4 and associated power module PS4 is located adjacent to both inductor L2 and associated power module PS2 and inductor L3 and associated power module PS3, while inductor L4 and associated power module PS4 are located diagonally opposite inductor L1 and associated power module PS1. Other arrangements are possible.

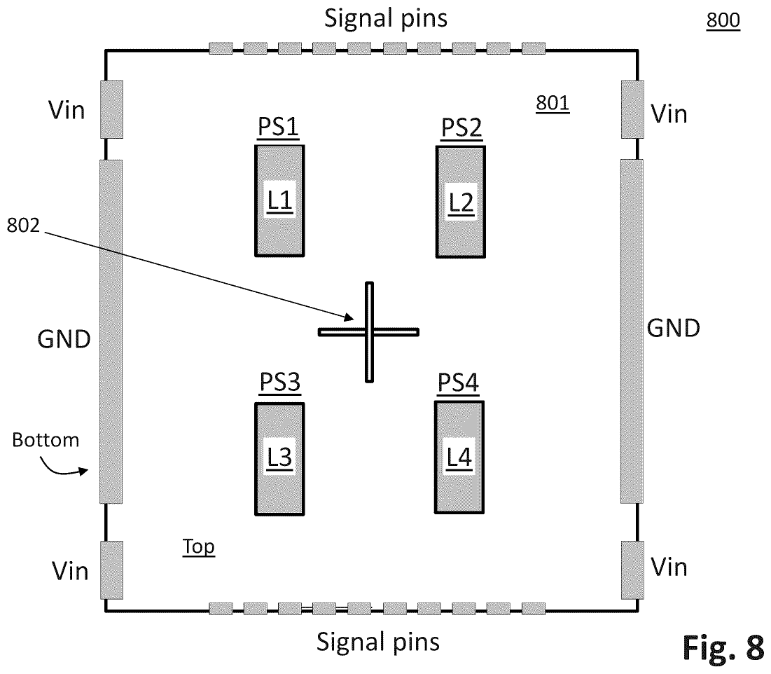

FIG. 8 shows a perspective view of another example power module that can implement an inductor with integrated conductors for power modules in one embodiment. FIG. 8 shows a top perspective view of a multi-phase (e.g., four-phase) power module 800 including an arrangement or configuration of inductors and conductors on the top surface of inductor core 801 similar to inductor core 101 described herein. As shown in FIG. 8, an opening 802, a slot, or a spacer spanning from the top surface of inductor core 801 to the bottom surface of inductor core 801 can be included for at least partially mitigating coupling issues that may arise from the inductors being in proximity to each other. Opening 802 may be disposed centrally within inductor core 801 between the first inductor winding, the second inductor winding, the third inductor winding, and the fourth inductor winding. Opening 802 may span between a bottom surface of inductor core 801 and top surface of inductor core 801. In one example, opening 802 may be in the shape of a cross including two or more planar members composed of non-magnetic materials having a lower permeability than that of the inductor core and arranged to have a cross-shaped cross section where the planar members may be interlocking in some manner.

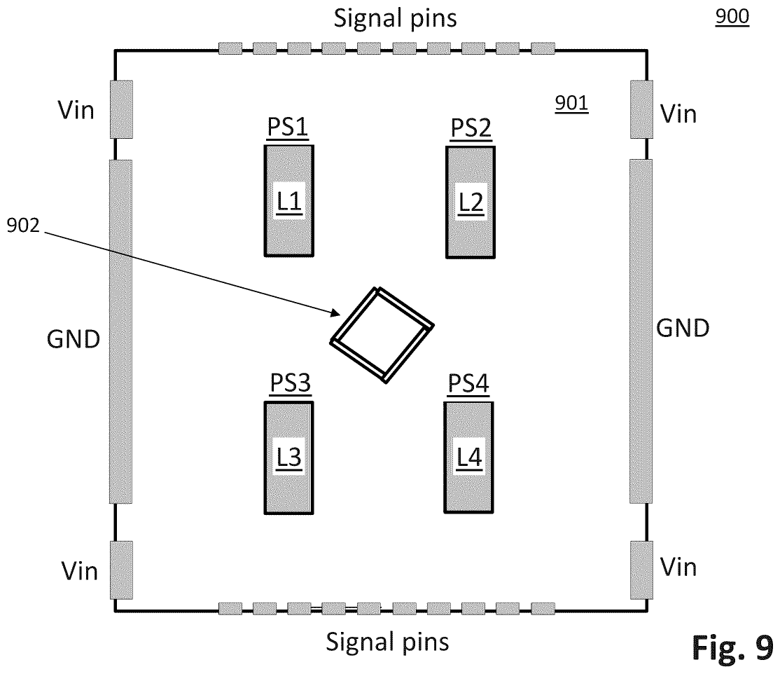

In another example, if the inductor core is a magnetic material (e.g., ferrite), then opening 802 may include a non-magnetic material, may be a region of reduced density of magnetic material (e.g., thinner or weaker connections), or opening 802 may be air (e.g., an air gap) to at least partially reduce, impede, or block magnetic coupling between adjacent inductors such as L1:L2, L2:L4, and/or diagonally opposed inductors such as L2:L3. In this manner, the presence of opening 802 may increase a reluctance of a coupling path between inductor L1 and adjacent inductor L2, inductor L2 and adjacent inductor L4, or increase reluctance of a magnetic coupling path between inductor L2 and diagonally opposite inductor L3, compared with a reluctance of a magnetic path around inductor L2 itself, to at least partially reduce and resolve coupling issues between adjacent and/or diagonally opposed inductors. Similarly, opening 802 may increase reluctance of a coupling path between inductor L1 and the adjacent inductors L2 and L3, as well as diagonally opposite inductor L4, etc. The size and/or shape of opening 802 can vary (see FIG. 9).

FIG. 9 is a diagram showing a perspective view of another example power module that can implement an inductor with integrated conductors for power modules in one embodiment. FIG. 9 shows a top perspective view of a multi-phase (e.g., four phases) power module 900 including an arrangement or configuration of inductors and conductors on the top surface of inductor core 901 similar to inductor core 101 described herein. As shown in FIG. 9, an opening 902 spanning from the top surface of inductor core 901 to the bottom surface of inductor core 901 can be included for resolving coupling issues that may arise from the inductors being in proximity to each other, as described above with reference briefly to FIG. 8.

Opening 902 may have a diamond-shaped (e.g., a rhombus) cross section which may be hollow (e.g., filled with air) or may be filled with another, non-magnetic material. Alternatively, opening 902 may have a cross-sectional profile of a square, a hexagon, an octagon, or a circle corresponding, for example, to a cross section of a cylinder, or other shape having a larger cross sectional void area compared with opening 802. For structural support between a top surface and a bottom surface of inductor core 901, a center region of opening 902 may be filled with the inductor core material having different magnetic properties, may be non-magnetic material, or may be air.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Relative terms such as substantially, approximately, and about may be used to describe relationships where some parameters such as angular relationship, length, height, width are not critical to the proper understanding of how to make and use the disclosed solutions. For example, substantially parallel may describe planar surfaces that each have a pitch that is within 10-degrees of each other, or less.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A structure comprising:
an inductor core having a plurality of surfaces; and
at least one conductor integrated with at least one surface of the plurality of surfaces of the inductor core.

2. The structure of claim 1, wherein the inductor core has six sides arranged in three pairs of opposing sides and surrounding an inductor core volume, each side of the inductor core has an external surface.

3. The structure of claim 2, wherein the at least one conductor passes through at least a portion of the inductor core volume.

4. The structure of claim 2,
wherein the at least one conductor integrated with at least one surface of the inductor core is included in a plurality of conductors, each of the plurality of conductors being integrated with at least one surface of the plurality of surfaces of the inductor core, and
wherein a subset of the plurality of conductors is at least one of an electrical conductor and a thermal conductor.

5. The structure of claim 4 further comprising:
an inductor winding disposed at least partially within the inductor core volume, the inductor winding and the inductor core forming an inductor, the inductor winding having a first lead attached to a first conductor of the plurality of conductors, the first conductor being integrated with at least one of the surfaces of the plurality of surfaces of the inductor core, the inductor winding having a second lead attached to a second conductor of the plurality of conductors, the second conductor being integrated with at least one of the plurality of surfaces of the inductor core.

6. The structure of claim 5, wherein the first conductor and the second conductor are integrated with one of a same surface of the plurality of surfaces of the inductor core and a different surface of the plurality of surfaces of the inductor core.

7. The structure of claim 5, further comprising:
a power stage disposed on a first surface of the inductor core and coupled to the inductor winding, the power stage being electrically coupled to a power source and a controller through a plurality of conductors integrated with a second surface of the inductor core to form a single-phase power controller.

8. The structure of claim 1, wherein the at least one conductor spans a plurality of inductor core surfaces.

9. The structure of claim 8, wherein the plurality of inductor core surfaces are at least one of:
disposed adjacent to each other, the at least one conductor being configured to span between two surfaces and four surfaces of the plurality of inductor core surfaces; and
disposed opposite from each other, the at least one conductor being configured to span between three surfaces and four surfaces of the plurality of inductor core surfaces.

10. The structure of claim 8, wherein the plurality of inductor core surfaces are disposed opposite from each other are parallel to each other.

11. The structure of claim 1, wherein the inductor core includes an opening disposed within the inductor core that spans between a bottom surface and top surface of the inductor core.

12. The structure of claim 11, wherein the opening has a cross-sectional profile of a cross, a square, a diamond, a hexagon, an octagon, and a circle.

13. An apparatus comprising:
an inductor core having six sides arranged in three pairs of substantially parallel surfaces and forming an inductor core volume;
a plurality of conductors, each of the plurality of conductors being integrated with at least one surface of the inductor core; and
an inductor winding disposed at least partially within the inductor core volume, the inductor winding and the inductor core forming an inductor, the inductor winding having a first lead attached to a first conductor of the plurality of conductors, the first conductor being integrated with at least one of the surfaces of the inductor core, the inductor winding having a second lead attached to a second conductor of the plurality of conductors, the second conductor being integrated with at least one of the surfaces of the inductor core.

14. The apparatus of claim 13, wherein the first conductor and the second conductor are integrated with one of
a same surface of the plurality of surfaces of the inductor core and
a different surface of the plurality of surfaces of the inductor core.

15. The apparatus of claim 13, wherein the inductor winding is a first inductor winding, the apparatus further comprising:
a second inductor winding disposed at least partially within the inductor core volume and disposed adjacent to the first inductor winding, the second inductor winding and the inductor core forming a second inductor, the second inductor winding having a third lead attached to a third conductor of the plurality of conductors, the third conductor being integrated with at least one of the surfaces of the inductor core, the second inductor winding having a fourth lead attached to a fourth conductor of the plurality of conductors, the fourth conductor being integrated with at least one of the surfaces of the inductor core.

16. The apparatus of claim 15, further comprising:
an opening disposed within the inductor core between the first inductor winding and the second inductor winding, the opening spans between a bottom surface of the inductor core and top surface of the inductor core,
wherein the opening has a cross-sectional profile of a cross, a square, a diamond, a hexagon, an octagon, and a circle.

17. The apparatus of claim 15 further comprising:
a first power stage disposed on a top surface of the inductor core and coupled to the first inductor winding, the first power stage being coupled to a power source and a first controller through a first plurality of conductors integrated with at least one of a plurality of side surfaces of the inductor core; and
a second power stage disposed on the top surface of the inductor core and disposed adjacent to the first power stage, the second power stage being coupled to the second inductor winding, the second power stage being coupled to the power source and a second controller through a second plurality of conductors integrated with at least one of the plurality of side surfaces of the inductor core,
wherein the first power stage coupled with the first inductor winding and the second power stage coupled with the second inductor winding form a dual-phase power module.

18. The apparatus of claim 17 further comprising:
a third inductor winding disposed at least partially within the inductor core volume and disposed adjacent to the first inductor winding and the second inductor winding, the third inductor winding and the inductor core forming a third inductor;
a third power stage disposed on the top surface of the inductor core and disposed adjacent to the second power stage, the third power stage being coupled to the third inductor winding, the third power stage being coupled to the power source and a third controller through a third plurality of conductors integrated with at least one of the plurality of side surfaces of the inductor core;
a fourth inductor winding disposed at least partially within the inductor core volume and disposed diagonally opposite the first inductor winding, the fourth inductor winding and the inductor core forming a fourth inductor; and
a fourth power stage disposed on the top surface of the inductor core and disposed adjacent to both the third power stage and the first power stage, the fourth power stage being coupled to the fourth inductor winding, the fourth power stage being coupled to the power source and a fourth controller through a fourth plurality of conductors integrated with at least one of the plurality of side surfaces of the inductor core,
wherein the first power stage coupled with the first inductor winding, the second power stage coupled with the second inductor winding, the third power stage coupled with the third inductor winding, and the fourth power stage coupled with the fourth inductor winding form a quad-phase power module.

19. The apparatus of claim 18, further comprising:
an opening disposed centrally within the inductor core between the first inductor winding, the second inductor winding, the third inductor winding, and the fourth inductor winding, the opening spans between a bottom surface of the inductor core and top surface of the inductor core,
wherein the opening has a cross-sectional profile of a cross, a square, a diamond, a hexagon, an octagon, and a circle.

20. A method of forming a structure comprising:
forming an inductor core having a plurality of surfaces; and
integrating at least one conductor with at least one surface of the plurality of surfaces of the inductor core.
